(19) United States
(12) Patent Application Publication
(10) Pub. No.: US 2025/0227902 A1
(43) Pub. Date: Jul. 10, 2025

(54) DOUBLE SIDED DISPLAY ASSEMBLY WITH BI-DIRECTIONAL FLOW THROUGH A COMMON, PARTITIONED HEAT EXCHANGER

(71) Applicant: Manufacturing Resources International, Inc., Alpharetta, GA (US)

(72) Inventor: Kevin O'Connor, Duluth, GA (US)

(21) Appl. No.: 18/408,317

(22) Filed: Jan. 9, 2024

(51) Int. Cl. H05K 7/20; G09F 9/302

(52) U.S. Cl. CPC H05K 7/20972; G09F 9/302; H05K 7/20436

(57) ABSTRACT

Display assemblies with bi-directional flow through a common, partition heat exchanger are provided. Side assemblies are connected to a structural framework and include a cover, an electronic display, and one or more channels. A heat exchanger is positioned between the side assemblies and within the structural framework. A closed loop airflow pathway includes a first portion including at least one of the channels of the first side assembly, a second portion including a first portion of the heat exchanger, distal from the first side assembly, a third portion including at least one of the channels of the second side assembly, and a fourth portion extending to the first portion and including a second portion of the heat exchanger, distal from the second side assembly.

### CROSS-REFERENCE TO RELATED APPLICATIONS

This application is filed as original and therefore makes no priority claim.

### TECHNICAL FIELD

Exemplary embodiments relate generally to double sided display assemblies with bi-directional flow through a common, partitioned heat exchanger as well as systems and methods related to the same.

### BACKGROUND AND SUMMARY OF THE INVENTION

Digital out of home (DOOH) advertising is becoming increasingly common. To accomplish such DOOH advertising, electronic displays are sometime placed within ruggedized housings to help the sensitive electronics withstand relatively harsh and varied environmental conditions. This may require at least partial enclosure and/or sealing of such units. The units themselves and/or ambient conditions (e.g., sunlight) may generate heat within the units. As the units may be at least partially sealed, thermal management systems are often needed to maintain internal temperatures and other conditions at acceptable levels, such as to accommodate the relatively sensitive electronic equipment located therein. It is known to use a combination of open loop(s) of ambient air and closed loop(s) of circulating gas to thermally manage displays. Examples of such units and known thermal management systems include the BOLDVU® display assemblies available from Manufacturing Resources International, Inc. of Alpharetta, Georgia (https://mri-inc.net/, Applicant for the Present Application).

Different components and desired unit profiles may require different components and/or component arrangements. For example, differing components and/or arrangements may affect airflow patterns and/or heat loading. This sometimes necessitates various thermal management considerations and designs.

A double-sided display assembly with bi-directional flow through a common, partitioned heat exchanger is provided along with related systems and methods. Side assemblies are connected to a structural framework. The side assemblies may be the same or substantially similar.

Each side assembly includes one or more channels, such as at least one closed loop channel. A rear channel between the side assemblies includes a common heat exchanger. Speta may extend within the rear channel to guide airflow. In exemplary embodiments, fan(s) drive circulating gas through a closed loop airflow pathway such that circulating gas exiting the at least one closed loop channel of a first one of the side assemblies is confined by a first set of one or more septa to travel into a distal portion of a closed loop portion of the heat exchanger before traveling along a rear surface of the second one of the side assembles in an opposing direction to an entrance to the at least one closed loop channel of a second one of the side assemblies. The circulating gas exiting the at least one closed loop channel of the second one of the side assemblies is confined by a second set of one or more septa to travel through a second portion of the closed loop portion of the heat exchanger distal from the second one of the side assemblies before traveling along a rear surface of the first one of the side assembles in an opposing direction to the entrance to the at least one closed loop channel of the first one of the side assemblies. In this fashion, the closed loop airflow pathway forms a loop within the unit. The septa and the heat exchanger may serve to partition the rear channel to separate portions of the loop. The closed loop airflow pathway may form a generally “S” or “Z” shape with parallel S's or Z's, and/or if the S or Z is considered as a bubble type such letter.

The at least one closed loop channel of each of the side assemblies may include a forward channel between a cover and display layer of an electronic display for the side assembly and a secondary channel between an illumination structure and the electronic display layer of the electronic display for the side assembly. While the circulating gas through the forward and rearward channels of a respective side assembly may extend substantially parallel, the flow(s) through the at least one closed loop channel of each respective side assembly may travel in opposing directions. The circulating gas flow(s) through the first and second portions of the closed loop portion of the heat exchanger may travel in opposing directions. The flows through the rear portions of the rear channel may extend in opposing directions.

One or more open loop airflow pathways may include at least one open loop channel provided at each of the side assemblies and an open loop portion of the heat exchanger.

Separations within the closed loop and/or between the closed loop and the ambient environment, any open loop airflow pathways, and/or other portions of the unit need not be perfect. For example, a hermetic seal is not necessarily required. Instead, separation may be in accordance with ingress protection code 65 or higher, for example.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical, similar, or equivalent features, and wherein:

FIG. 1 is perspective view of an exemplary display assembly in accordance with the present invention;

FIG. 2 is a top sectional view taken along section line A-A and illustrating an exemplary airflow pathway and airflow velocities within the display assembly when fans are activated;

FIG. 3 is the top sectional view of FIG. 2 with the exemplary airflow pathway illustrated in isolation; and

FIG. 4 is the top sectional view of FIG. 2 with exemplary airflow velocities illustrated in isolation.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

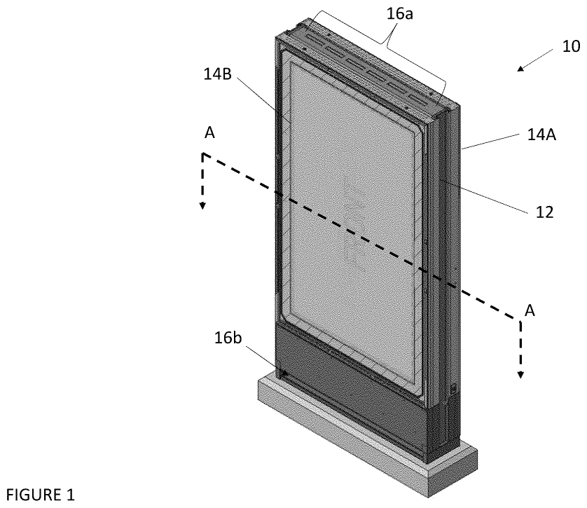

FIG. 1 illustrates an exemplary display unit 10 in accordance with the present invention. The unit 10 may comprise a first side assembly 14A and a second side assembly 14B connected to a structural framework 12. The first and second side assemblies 14A, 14B may be mounted to opposing sides of the framework 12. The framework 12 may include one or more structural members, panels, combinations thereof, or the like. The framework 12 may be configured for mounting to a ground surface (e.g., sidewalk, parking lot, etc.), street furniture (e.g., bus shelter, railing, pole, etc.), combinations thereof, or the like, and/or may incorporate the same.

Any number and/or arrangement of the side assemblies 14 and framework 12 may be utilized. While each side assembly 14 comprises an electronic display in exemplary embodiments, such is not necessarily required. For example, one or more of the side assemblies may include a poster cavity (illuminated or otherwise), door/access panel, combinations thereof, or the like in other exemplary embodiments, while preferably including similar structure (e.g., panels) to provide the associated airflow pathway(s) shown and/or described herein.

In exemplary embodiments, without limitation, the side assemblies 14 are movably mounted to the framework 12, such as by way of hinges located along an upper portion or side of the side assemblies 14 to allow rotation about a substantially (e.g., within 20 degrees) horizontal or vertical axis, gas struts, single or multi-arm linkages, combinations thereof, or the like. This may permit servicing of the unit 10, such as internal components and/or side assemblies 14, including on site servicing, interchange and/or replacement.

Intakes and/or exhausts 16 may be provided at the framework 12 and/or the side assemblies 14 for ingesting and/or exhausting ambient air. For example, without limitation, a common or separate intake(s) 16A may be provided at an upper portion of the framework 12 for the side assemblies 14 and/or heat exchanger 38 while separate, dedicated exhausts 16B are provided at a lower portion of each side assembly 14 and/or the heat exchanger 38. Various common and/or separate intakes and/or exhausts 16 may be utilized for one or more of the side assemblies 14 and/or heat exchanger 38. The number and/or arrangement of intakes/exhausts 16 is exemplary and not intended to be limiting. Internal intakes/exhausts may be provided for moving air into and/or out of each of the side assemblies 14. The intakes and/or exhausts 16 may ingest and/or exhaust ambient air through one or more open loop airflow pathways within the unit 10 as further discussed herein.

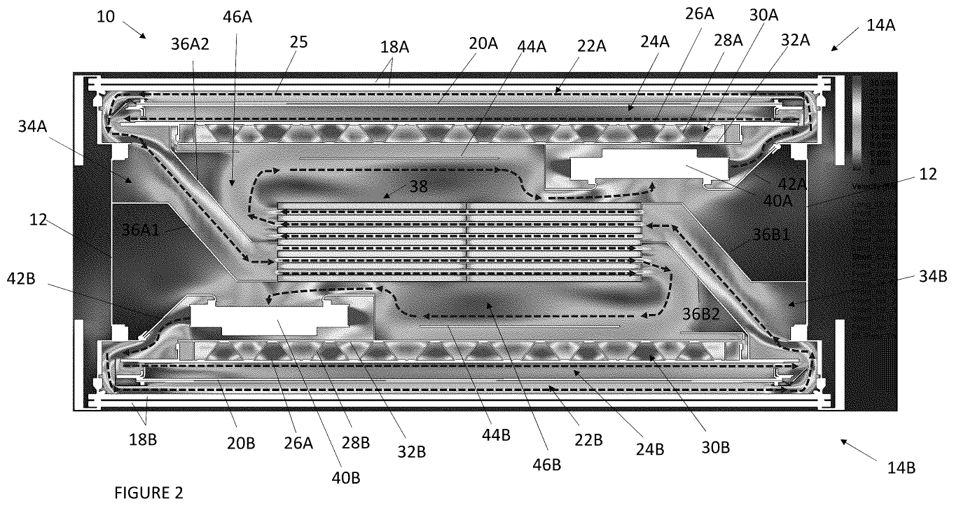

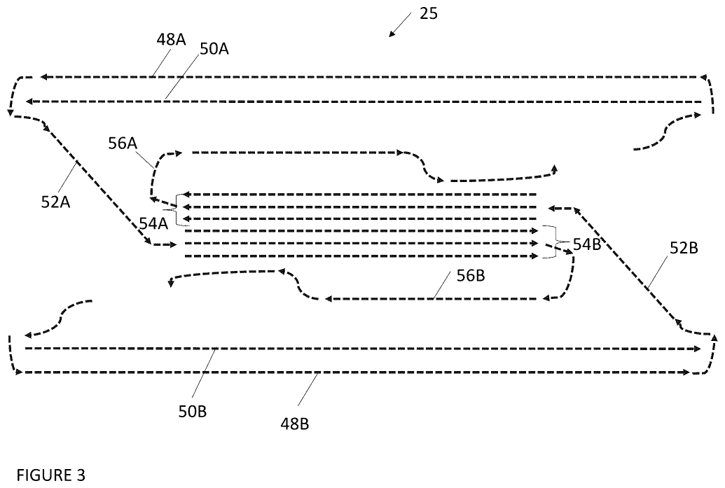

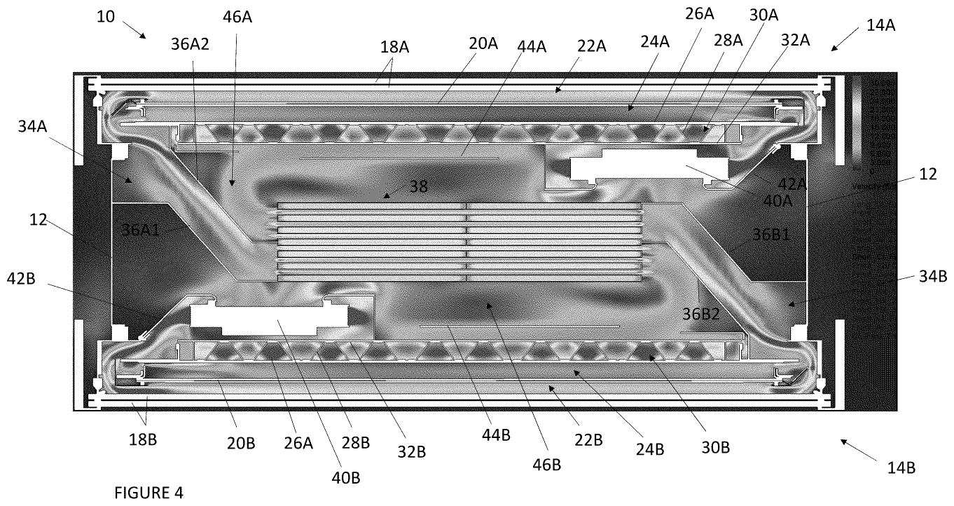

FIG. 2 through FIG. 4 illustrate exemplary sectional views of the unit 10. More specifically, FIG. 2 illustrates an exemplary sectional view with structural Title: Double Sided Display Assembly with Bi-Directional Flow Through a Common, Partitioned Heat Exchanger components, exemplary airflow velocities, and an exemplary generalized closed loop airflow pathway 25 illustrated. FIG. 3 illustrates the generalized closed loop airflow pathway 25 in isolation for ease of viewing. FIG. 4 illustrates the structural components and exemplary airflow velocities in isolation for ease of viewing.

Each of the side assemblies 14A, 14B may be the same or substantially similar in exemplary embodiments, without limitation. This may reduce part count and make replacement easy. The side assemblies 14A, 14B may be numbered similarly but with an “A” or “B” designator. The side assemblies 14A, 14B and/or their components may be referred to by their base designator herein (e.g., 14A, 14B as 14, 18A, 18B as 18, etc.).

Each of the side assemblies 14 may comprise a cover 18. The covers 18A, 18B may each comprise a single or multiple layers. The covers 18 may be transparent or translucent. The cover 18 layers may comprise glass, acrylic, one or more polymers, combinations thereof, or the like. The covers 18 may comprise one or more polarizers, anti-reflection films, combinations thereof, or the like.

An electronic display layer 20A, 20B may be positioned rearward of each of the covers 18A, 18B, respectively. The electronic display layers 20 may comprise liquid crystals, though other types of electronic displays and/or electronic display layers 20 may be utilized (e.g., OLED). The electronic display layers 20 may be spaced apart from the covers 18 to create forward airflow channels 22A, 22B. In this manner, portions 48A, 48B of the exemplary closed loop airflow 25 may extend within each of the forward airflow channels 22, between the covers 18 and the electronic display layers 20. This portion 48 of the closed loop airflow 25 may reduce heat generated from solar loading experienced at and/or through the cover(s) 18, for example, without limitation.

An illumination structure 26A, 26B may be positioned rearward of each of the electronic display layer 20A, 20B. The illumination structures 26 may comprise backlights for the electronic display layers 20. For example, without limitation, the illumination structures 26 may each comprise one or more substrates (e.g., PCB), each with a number of illumination elements (e.g., LEDs) positioned thereon which, when activated, shine light at and/or through the electronic display layers 20. The illumination structures 26 may be spaced apart from the electronic display layers 20 to create secondary airflow channels 24A, 24B. In this manner, other portions 50A, 50B of the exemplary closed loop airflow 25 may extend within each of the secondary airflow channels 24, between the illumination structures 26 and the electronic display layers 20. This may enhance thermal management and/or control forces provided at the electronic display layers 20. For example, without limitation, this portion 50 of the closed loop airflow 25 may reduce heat generated from illumination structures 26. The illumination structures 26 need not necessarily include illumination elements, such as where self-illuminating electronic displays are utilized (e.g., OLED). The secondary airflow channels 24 may extend at least substantially (e.g., within 20 degrees) parallel with the forward airflow channels 22, at least in part.

In exemplary embodiments, without limitation, the portions 48A, 50A, 48B, 50B of the exemplary closed loop airflow 25 within the respective side assemblies 14A, 14B may extend within each of the forward airflow channels 22A, 22B and secondary Title: Double Sided Display Assembly with Bi-Directional Flow Through a Common, Partitioned Heat Exchanger airflow channels 24A, 24B in at least substantially (e.g., within 20 degrees) opposite directions.

Open loop airflow channels 30A, 30B may be provided in each of the side assemblies 14A, 14B, though such is not necessarily required. Rear panels 32A, 32B may be provided, each of which is located rearward of, and spaced apart from, a respective one of the illumination structure 26A, 26B and/or forms a rear portion of the respective one of the open loop airflow channels 30A, 30B and/or the side assemblies 14A, 14B.

A corrugated layer 28A, 28B may optionally be provided within each of the open loop airflow channels 30A, 30B. The corrugated layer 28 may increase surface area within the channels 30. The open loop airflow channels 30 may be fluidly connected to the intakes/exhausts 16. The open loop airflow channels 30 may provide cooling for the illumination structures 26, which may normally provide a significant heat source, by way of non-limiting example.

Septa 36A1, 36A2, 36B1, 36B2 may extend from the side assemblies 14 and/or framework 12 to direct airflow exiting the forward airflow channels 22 and/or secondary airflow channels 24, which may be at least partially combined, toward a common heat exchanger 38 located between the side assemblies 14. In exemplary embodiments, the common heat exchanger 38 is fixed to the framework 12. The septa 36 may be fixed to one or more of: the common heat exchanger 38, the framework 12, and a respective one of the side assemblies 14. The septa 36 and/or heat exchanger 38 may serve as partitions within the space between the side assemblies 14 and within the framework 12, such as to compartmentalize and/or divide the space. The septa 36 may confine airflow traveling into and/or out of the heat exchanger 38 for example, without limitation.

In exemplary embodiments, a first one of the septa 36A1, 36B1 associated with a respective one of the side assemblies 14A, 14B extends from the respective one of the side assemblies 14A, 14B to the heat exchanger 38 and a second one of the one of the septa 36A2, 36B2 associated with the respective one of the side assemblies 14A, 14B extends from the structural framework 12 to the heat exchanger 38. The septa 36 may extend at non-parallel, non-perpendicular angle(s) relative to a face of the side assemblies 14 in exemplary embodiments, without limitation.

The heat exchanger 38 may comprise a multi-layer heat exchanger. Preferably, the heat exchanger 38 comprises alternating layers for portions 54B, 54A of the closed loop airflow 25 and open loop airflow. Preferably, the alternating layers are arranged for flow primarily in generally (e.g., within 20 degrees) perpendicular directions from one another. For example, without limitation the closed loop airflow 25 may travel primarily in a generally horizontal direction while open loop airflow may travel primarily in a generally vertical direction.

In exemplary embodiments, without limitation, the partitions 36 may direct the airflow to a distal portion of heat exchanger 38 relative to the respective side assembly 14 from which the airflow is exiting. The airflow 54B may flow through one or more layers of the heat exchanger 38. One or more of the layers of the heat exchanger 38, and/or the septa 36, may serve to separate a first portion 54B of the closed loop airflow 25 exiting the first side assembly 14A from a second portion 54A of the closed loop airflow 25 exiting the second side assembly 14B such that the first and second portions 54A, 54B of the closed loop airflow 25 within the heat exchanger 38 are provided in a generally counter flow type arrangement.

Airflow exiting the heat exchanger 38 may be at least partially recombined and extend through rear channels 46A 46B located rearward of the side assemblies 14A, 14B, within the framework 12, and outside of the heat exchanger 38. Such travel may be further confined and/or directed, at least in part, by the septa 36. In exemplary embodiments, without limitation, these portions 56A, 56B of the closed loop airflow 25 may extend over and/or under electronic components 44A, 44B. The electronic components 44A, 44B comprise one or more electronics (e.g., microchips, power supplies, video players, network connectivity devices, sensors, combinations thereof, or the like). The electronic components 44A, 44B may be mounted to substrates which are connected to, and spaced apart from, the rear panels 32. In other exemplary embodiments, without limitation, the electronic components 44A, 44B are directly mounted to the rear panels 32. The general bend in the closed loop airflow pathway 25 from the heat exchanger 38 to the fans 40 may cause the portion 56 of the circulating gas in the closed loop airflow pathway 25 to contact the electronic components 44 and/or a rear surface of the open loop channel 30 and/or rear panel 32, such as to enhance heat transfer.

One or more fans 40A, 40B may be provided within each of the rear channels 46A, 46B. For example, without limitation, each of the fans 40 may be connected to the rear panel 32 of the respective side assembly 14. The fans 40 may comprise a housing 42 that preferably extends between an entrance to the respective fan 40 and the respective side assembly 14, such as to guide the circulating air exiting the Title: Double Sided Display Assembly with Bi-Directional Flow Through a Common, Partitioned Heat Exchanger fan 40 towards the respective forward channel 22 and secondary channel 24 of the respective side assembly 14. In exemplary embodiments, without limitation, the fans 40 comprise centrifugal type fans, though such is not necessarily required.

The open loop airflows extending within the unit 10, such as within the open loop airflow channels 30A, 30B and heat exchanger 38 may be entirely separate and have separate intakes and/or exhausts 16, for example, or may be common, at least in part, any may share at least some of the intakes and/or exhausts 16.

The closed loop airflow pathways 25 illustrated is intended to convey a generalized, exemplary flow pathway and/or airflow velocities.

While the terms closed loop, circulating gas, or similar are sometimes used herein, the display unit 10, airflow pathways, and/or individual passageways, channels, etc. need not necessarily be hermetically sealed. Preferably, the separation between a least the closed loop airflow pathways 25 and the open loop airflow pathway(s) and/or ambient environment is sufficient to meet or exceed one or more of ingress protection (IP) 65, 66, 67, or more stringent, such as in accordance with the standards advanced by the International Electrotechnical Commission of Geneva, Switzerland (https://www.iec.ch/ip-ratings). Gaskets, caulking, solid materials, combinations thereof, or the like may be used to accomplish such separation and/or sealing.

The open loop airflow pathway(s) may be those in direct fluid connection with the ambient environment.

The disclosed embodiment(s) may facilitate adequate thermal management (e.g., cooling) during normal operations for a wide variety of environmental conditions. Alternatively, or additionally, the disclosed embodiment(s) may facilitate a relatively small footprint and/or occupation of space, which may be particularly important for installation in a small space (e.g., narrow sidewalk) or otherwise congested population center which space is highly valued. The disclosed embodiment(s) may be particularly suitable for relatively narrow, elongated units 10, by way of non-limiting example, which may otherwise provide insufficient surface area for heat exchange.

Alternatively, or additionally, the disclosed units 10 may not require any pass-through devices for the closed loop airflow pathway 25, at least, which can be difficult to adequately seal and provide certain complexities in manufacturing and/or maintenance.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention.

Certain operations described herein may be performed by one or more electronic devices. Each electronic device may comprise one or more processors, electronic storage devices, executable software instructions, combinations thereof, and the like configured to perform the operations described herein. The electronic devices may be general purpose computers or specialized computing devices. The electronic Title: Double Sided Display Assembly with Bi-Directional Flow Through a Common, Partitioned Heat Exchanger devices may comprise personal computers, smartphones, tablets, databases, servers, or the like. The electronic connections and transmissions described herein may be accomplished by one or more wired or wireless connectively components (e.g., routers, modems, ethernet cables, fiber optic cable, telephone cables, signal repeaters, and the like) and/or networks (e.g., internets, intranets, cellular networks, the world wide web, local area networks, and the like). The computerized hardware, software, components, systems, steps, methods, and/or processes described herein may serve to improve the speed of the computerized hardware, software, systems, steps, methods, and/or processes described herein. The electronic devices, including but not necessarily limited to the electronic storage devices, databases, controllers, or the like, may comprise and/or be configured to hold, solely non-transitory signals.

What is claimed is:

1. A display assembly comprising:
a structural framework;
side assemblies, each connected to the structural framework and comprising a cover, an electronic display, and one or more channels;
a heat exchanger positioned between the side assemblies and within the structural framework; and
a closed loop airflow pathway comprising:
a first portion comprising at least one of the one or more channels of a first one of the side assemblies;
a second portion extending between the first portion and a third portion of the closed loop airflow pathway, said second portion comprising a first portion of the heat exchanger, distal from the first one of the side assemblies;
the third portion extending between the second portion and a fourth portion of the closed loop airflow pathway, said third portion comprising at least one of the one or more channels of a second one of the side assemblies; and
the fourth portion extending to the first portion of the closed loop airflow pathway and comprising a second portion of the heat exchanger, distal from the second one of the side assemblies.

2. The display assembly of claim 1 further comprising:
one or more fans, which when activated, move circulating gas through the closed loop airflow pathway, including through the first portion of the heat exchanger in a first direction and through the second portion of the heat exchanger in a second direction opposing the first direction.

3. The display assembly of claim 2 wherein:
said one or more fans are configured to, when activated, move said circulating gas through the at least one of the one or more channels of the first one of the side assemblies in the second direction before entering the first portion of the heat exchanger, and through the at least one of the one or more channels of the second one of the side assemblies in the first direction before entering the second portion of the heat exchanger.

4. The display assembly of claim 3 further comprising:
a first set of one or more septa extending from an exit of each of the at least one of the one or more channels of the first one of the side assemblies to the first portion of the heat exchanger; and
a second set of one or more septa extending from an exit of each of the at least one of the one or more channels of the second one of the side assemblies to the second portion of the heat exchanger.

5. The display assembly of claim 4 wherein:
Title: Double Sided Display Assembly with Bi-Directional Flow Through a Common, Partitioned Heat Exchanger the first set of one or more septa comprises a first septa extending from the first one of the side assemblies to the heat exchanger and a second septa extending from the structural framework to the heat exchanger; and
the second set of one or more septa comprises a third septa extending from the second one of the side assemblies to the heat exchanger and a fourth septa extending from the structural framework to the heat exchanger.

6. The display assembly of claim 4 further comprising:
a rear channel provided between the side assemblies and within the structural framework, wherein said rear channel is partitioned into a first portion extending along a rear surface of the first one of the side assemblies and a second portion extending along a rear surface of the first one of the side assemblies by the heat exchanger and at least some of the septa, and wherein said heat exchanger is located within the rear channel.

7. The display assembly of claim 6 wherein:
the first set of one or more septa partition the rear channel into a third portion extending from an exit of the at least one of the one or more channels of the first one of the side assemblies to the first portion of the heat exchanger; and
the second set of one or more septa partition the rear channel into a fourth portion extending from an exit of the at least one of the one or more channels of the second one of the side assemblies to the second portion of the heat exchanger.

8. The display assembly of claim 6 wherein:
Title: Double Sided Display Assembly with Bi-Directional Flow Through a Common, Partitioned Heat Exchanger said one or more fans are configured to, when activated, move said circulating gas through the first portion of the rear channel in the first direction and the second portion of the rear channel in the second direction.

9. The display assembly of claim 8 wherein:
the first portion of the rear channel is fluidly interposed between the second portion of the heat exchanger and the at least one channel of the first one of the side assemblies; and
the second portion of the rear channel is fluidly interposed between the first portion of the heat exchanger and the at least one channel of the second one of the side assemblies.

10. The display assembly of claim 6 further comprising:
a first set of one or more electronic components for operating the first one of the side assemblies located within the first portion of the rear channel; and
a second set of one or more electronic components for operating the second one of the side assemblies located within the second portion of the rear channel.

11. The display assembly of claim 2 wherein:
each of the one or more fans comprises a first set of one or more fans connected to a first one of the side assemblies and a second set of one or more fans connected to a second one of the side assemblies.

12. The display assembly of claim 11 wherein:
each of the one or more fans comprises a centrifugal type fan blade and a fan housing extending about at least part of the respective one of the fan blades and over an entrance to the at least one channel of the respective one of the side assemblies to which the respective one of the fans is connected.

13. The display assembly of claim 1 wherein:
the electronic display of each of the side assemblies comprises an electronic display layer located rearward of, and spaced part from, the cover; and
the at least one of the one or more channels of each of the side assemblies comprises a forward channel located between the cover and the electronic display layer of the respective one of the side assemblies.

14. The display assembly of claim 13 wherein:
the electronic display of each of the side assemblies comprises an illumination structure located rearward of, and spaced part from, the electronic display layer; and
the at least one of the one or more channels of each of the side assemblies comprises a secondary channel located between the illumination structure and the electronic display layer of the respective one of the side assemblies.

15. The display assembly of claim 14 wherein:
the electronic display layer of each of the side assemblies comprises a liquid crystal type display; and
the illumination structure of each of the side assemblies comprises a direct backlight for the electronic display layer of the respective one of the side assemblies; and
said direct backlight of each of the side assemblies comprises a printed circuit board and a number of light emitting diodes.

16. The display assembly of claim 1 further comprising:
one or more open loop airflow pathways comprising a third portion of the heat exchanger.

17. The display assembly of claim 16 wherein:
the one or more channels of each of the side assemblies comprises an open loop channel located along a rear surface of the illumination structure;
the open loop channel of each of the side assemblies forms part of the one or more open loop airflow pathways; and
the heat exchanger comprises layers which alternate between forming part of the one or more open loop airflow pathways and the closed loop airflow pathway.

18. The display assembly of claim 16 wherein:
the closed loop airflow pathways are separate from an ambient environment and the one or more open loop airflow pathways in accordance with at least ingress protection code 65.

19. A display assembly comprising:
a structural framework;
a first and second side assembly, each connected to the structural framework and comprising a cover, an electronic display, at least one open loop channel and at least one closed loop channel;
a heat exchanger positioned between the first and second side assemblies and within the structural framework and comprising a closed loop portion and an open loop portion;
a closed loop airflow pathway comprising:
a first portion comprising the at least one closed loop channel of each of the first side assembly;
a second portion extending between the first portion and a third portion comprising a first portion of the closed loop portion of the heat exchanger, which is distal from the first side assembly;
the third portion extending between the second portion and a fourth portion comprising the at least one closed loop channel of each of the second side assembly; and
the fourth portion extending to the first portion and comprising a second portion of the closed loop portion of the heat exchanger, which is distal from the second side assembly;
one or more open loop airflow pathways comprising the at least one open loop channel of each of the side assemblies and the open loop portion of the heat exchanger; and
one or more fans located along the closed loop airflow pathway.

20. An electronic displays apparatus, comprising:
two individual electronic displays configured in a back-to-back arrangement in a housing;
a shared heat exchanger positioned between the two displays, and within the housing;
at least one fan in the first of the two displays and at least another fan in the second of the two displays; and
a pathway for cooling air to circulate inside the displays and the housing, said pathway defined to comprise the route cooling air is enabled to travel through said apparatus in the space between a cover glass and display panel on the first of the two displays, then through a first portion of the heat exchanger in a first direction, exiting the heat exchanger and circulating between a cover glass and the display panel of the second of the two displays, then through a second portion of the heat exchanger in a second direction opposite of said first direction, then back to the first of the two displays, such that during operation of said fans the cooling air continues in a continuous cooling air stream in the pathway.
